(19) United States
(12) Patent Application Publication
(10) Pub. No.: US 2011/0133362 A1
(43) Pub. Date: Jun. 9, 2011

(54) MOLD RELEASE FILM FOR MANUFACTURING SEMICONDUCTOR RESIN PACKAGE AND SEMICONDUCTOR RESIN PACKAGE MANUFACTURING METHOD USING SAME

(75) Inventors: Takayuki Sanada, Chiba (JP); katsumi Noritomi, Chiba (JP); Tomoya Matayoshi, Chiba (JP)

(73) Assignee: MITSUI CHEMICALS, INC., Tokyo (JP)

(21) Appl. No.: 13/058,411

(22) PCT Filed: Aug. 26, 2009
(86) PCT No.: PCT/JP2009/004143

§ 371 Date: Feb. 10, 2011

(30) Foreign Application Priority Data
Aug. 28, 2008 (JP) 2008219815

(51) Int. Cl. H01L 21/56; B32B 27/32; B32B 27/08; B32B 27/34; B32B 5/00

(52) U.S. Cl. 264/272.17; 428/523; 428/476.3; 428/475.8; 428/332

(57) ABSTRACT

Provided are: a mold release film, which has excellent mold releasability to a semiconductor resin package and does not easily generate warpage, wrinkles and the like; and a method for obtaining a semiconductor resin package having excellent dimensional accuracy by using such mold release film. The mold release film for manufacturing a semiconductor resin package has one or more base material layers (C), a pair of outermost layers (A) which sandwich the base material layers (C) and contain a 4-methyl-1-pentene polymer as a main component, and a pair of adhesive layers (B) which adhere together the base material layers (C) and the outermost layers (A).

### TECHNICAL FIELD

The present invention relates to mold release films for manufacturing semiconductor resin packages, and manufacturing methods of semiconductor resin packages using the same.

### BACKGROUND ART

Semiconductor chips generally come in the form of semiconductor resin packages in which they are encapsulated with encapsulating material. A semiconductor resin package is generally manufactured by transfer molding wherein one or more semiconductor chips are placed in the cavity of a mold followed by filling of the entire cavity with an encapsulating material which contains epoxy resin as a main component. The conventional transfer molding technique has the disadvantages of: 1) reducing work efficiency; 2) shortening mold life; and 3) increasing the likelihood of generating burrs on the semiconductor resin package. Reduced work efficiency is attributed to the necessity to clean the mold, as encapsulating materials sometimes soil the mold inner surface. Shorter mold life is due to the wear on the mold inner surface.

In order to overcome these drawbacks, a molding technique has been proposed that involves placing a mold release film such as a polytetrafluoroethylene (PTFE) film inside the cavity of a mold, a technique also known as “film assisted-molding”. However, it is difficult with this approach to provide a semiconductor resin package of desired shape because PTFE films tend to develop wrinkles when placed in the mold cavity. Moreover, PTFE films have the drawback of being difficult to dispose of as they generate fluorine gas when burned.

As another example of such a mold release film used for separating a semiconductor resin package from the mold, there is proposed a mold release film that includes two different functional layers: one separating the mold release film from a molded article (layer A); and the other exhibiting heat resistance to heat generated upon molding (layer B), wherein releasability from a molded article is controlled to fall within a specific range (see, e.g., Patent Literature 1). Specifically, Patent Literature 1 discloses a 3-layer mold release film consisting of a poly(4-methyl-1-pentene) layer, an adhesive layer, and a PET layer.

As still another example of a mold release film, there is proposed a 5-layer film consisting, in order, of layer A (surface layer), layer B (adhesive layer), layer C (base material layer), layer B′ (adhesive layer), and layer A′ (surface layer), wherein layer A and layer A′ (surface layers) contain a 4-methyl-1-pentene polymer resin (see, e.g., Patent Literature 2). Patent Literature 2 discloses that this film is suitable as a mold release film used for manufacturing of a multilayer printed circuit board.

### CITATION LIST

### Patent Literature

[PTL 1] Japanese Patent Application Laid-Open No. 2002-158242

[PTL 2] Japanese Patent Application Laid-Open No. 2004-82717

### SUMMARY OF INVENTION

### Technical Problem

The mold release film disclosed by Patent Literature 1 has a multilayer structure which is asymmetrical with respect to the center layer, and therefore, is more prone to warpage. Thus, when warpage occurs, it is difficult to stably secure the mold release film, placed into the cavity of a mold as a mold release film, to the mold cavity surface by vacuum suction due to the development of unwanted lengthwise wrinkles, poor adhesion to the mold cavity surface, etc. Lengthwise wrinkles refer to wrinkles that are formed on the mold release film along its length.

As described above, in some cases, warpage or wrinkling inhibits stable securing of a mold release film to the mold inner surface. As a consequence, in some cases, the shapes of wrinkles or other deformations formed in the mold release film are transferred to the resultant semiconductor resin package, a molded article, resulting in failure to obtain a semiconductor resin package of desired shape. There were also attempts to eliminate warpage of the mold release film while a semiconductor resin package is being manufactured, but to no avail; the attempted method not only resulted in the reduction of work efficiency, but also was unable to manufacture a semiconductor resin package of desired shape stably.

Specifically, there remains a need in the art to provide a mold release film that not only offers excellent semiconductor resin package releasability but also are less prone to warpage and wrinkling, in order to attain semiconductor resin packages of desired shape (i.e., semiconductor resin packages with good dimensional accuracy). It is therefore an object of the present invention to provide a mold release film that offers excellent semiconductor resin package releasability as well as is less prone to warpage and wrinkling; and a method of manufacturing a semiconductor resin package with good dimensional accuracy using the same.

### Solution to Problem

A first aspect of the present invention relates to mold release films given below.
[1] A mold release film for manufacturing a semiconductor resin package including:

at least one base material layer C;

a pair of outermost layers A which sandwiches base material layer C and contains a 4-methyl-1-pentene polymer as a main component; and

a pair of adhesive layers B which bonds outermost layers A to base material layer C.
[2] The mold release film according to [1] above, wherein base material layer C contains a polyamide resin, and adhesive layers B contain a modified 4-methyl-1-pentene polymer obtained by modifying a 4-methyl-1-pentene polymer with a unsaturated carboxylic acid and/or acid anhydride thereof.
[3] The mold release film according to [1] or [2] above, wherein adhesive layers B contains a modified 4-methyl-1-pentene polymer obtained by graft-modifying a 4-methyl-1-pentene polymer with maleic anhydride.
[4] The mold release film according to [2] or [3] above, wherein the polyamide resin is polyamide 6 or polyamide 66.
[5] The mold release film according to any one of [1] to [4] above, wherein the mold release film comprises one base material layer C.
[6] The mold release film according to any one of [1] to [5] above, wherein the total thickness of the pair of outermost layers A and the pair of adhesive layers B is 32 μm or less.
[7] The mold release film according to any one of [1] to [6] above, wherein the release film has a symmetrical multilayer structure in which base material layer C is the center layer.
[8] The mold release film according to any one [1] to [7] above, wherein the mold release film is used in a manufacturing process of a semiconductor resin package which includes the steps of:

placing a semiconductor chip in a cavity of the mold;

placing the mold release film between the semiconductor chip and an inner surface of the mold;

injecting an encapsulating material into the cavity of the mold to encapsulate the semiconductor chip therein; and

separating the semiconductor chip encapsulated with the encapsulating material from the release film.

A second aspect of the present invention relates to a method of manufacturing a semiconductor resin package using a release film, given below.
[9] A method of manufacturing a semiconductor resin package including:

placing a semiconductor chip into a cavity of a mold;

placing the mold release film according to any one of [1] to [7] above between the semiconductor chip and an inner surface of the mold;

injecting an encapsulating material into the cavity of the mold to encapsulate the semiconductor chip therein; and

separating the semiconductor chip encapsulated with the encapsulating material from the release film.

### Advantageous Effects of Invention

The present invention can provide a mold release film that offers excellent semiconductor resin package releasability as well as is less prone to warpage and wrinkling. Using the mold release film upon manufacturing of a semiconductor resin package, it is possible to provide a semiconductor resin package with good dimensional accuracy.

### BRIEF DESCRIPTION OF DRAWINGS

FIG. 1 is a schematic view illustrating an example of a structure of a mold release film according to an embodiment of the present invention;

FIGS. 2a to 2d illustrate an example of a first step of a manufacturing method of a semiconductor resin package according to an embodiment of the present invention;

FIG. 3 illustrates an example of a second step of a manufacturing method of a semiconductor resin package according to an embodiment of the present invention;

FIG. 4 illustrates an example of a third step of a manufacturing method of a semiconductor resin package according to an embodiment of the present invention;

FIG. 5 illustrates an example of a process of reloading a mold release film; and

FIG. 6 is an illustration for explaining the measurement of the depth of a wrinkle generated in a side surface of a semiconductor resin package.

### DESCRIPTION OF EMBODIMENTS

1. Mold Release Film for Manufacturing a Semiconductor Resin Package

A mold release film for manufacturing a semiconductor resin package (hereinafter “mold release film”) according to the present invention includes base material layer C; a pair of outermost layers A which sandwiches base material layer C and contains a 4-methyl-1-pentene polymer as a main component; and a pair of adhesive layers B, each provided between base material C and outermost layer A.

The mold release film according to the present invention is placed into the cavity of a mold in the process of encapsulating a semiconductor chip with encapsulating resin therein. By providing the mold release film, the semiconductor chip encapsulated with the encapsulating resin, or a semiconductor resin package, can be readily released from the mold.

A pair of outermost layers A is outermost layers placed on both sides of the mold release film, one contacting a semiconductor resin package (molded article), and the other contacting the cavity surface of a mold. Thus, outermost layers A are required to have both excellent heat resistance and mold releasability.

Outermost layer A contains a 4-methyl-1-pentene polymer as a main component. 4-Methyl-1-pentene polymers not only do not melt at a mold temperature during manufacturing of a semiconductor resin package for their high melting points of 220-240° C., but also offer excellent releasability for their low surface energies. Herein, all value ranges are inclusive for both of the minimum and maximum.

A 4-methyl-1-pentene polymer refers to either a homopolymer of 4-methyl-1-pentene (4-methyl-1-pentene homopolymer) or a copolymer of 4-methyl-1-pentene and other monomer(s) than 4-methyl-1-pentene (4-methyl-1-pentene copolymer).

Examples of other monomers contained in 4-methyl-1-pentene copolymers include C₂₋₂₀ α-olefins. Examples of C₂₋₂₀ α-olefins include ethylene, propylene, 1-butene, 1-hexene, 1-heptene, 1-octene, 1-decene, 1-tetradecene, 1-hexadecene, 1-heptadecene, 1-octadecene, and 1-eicosene. These α-olefins may be used alone or in combination.

Among C₂₋₂₀ α-olefins, it is preferable to employ C₇₋₂₀ α-olefins, more preferably C₈₋₂₀ α-olefins, and further preferably C₁₀₋₂₀ α-olefins.

In a 4-methyl-1-pentene copolymer, the ratio of the repeating unit derived from 4-methyl-1-pentene is preferably 93 mass % or more, more preferably 93-99 mass %, and further preferably 95-98 mass %. 4-Methyl-1-pentene copolymers which meet this requirement offer excellent rigidity derived from 4-methyl-1-pentene as well as excellent moldability derived from the α-olefin.

The melt flow rate (MFR) of the 4-methyl-1-pentene polymer, as measured in accordance with ASTM D1238 at a load of 5.0 kg and at 260° C., is preferably 0.5-250 g/10 min, more preferably 1.0-150 g/1. If MFR falls within the range, the polymer has excellent moldability and mechanical properties.

The 4-methyl-1-pentene polymer can be prepared by any desired process; for example, 4-methyl-1-pentene can be polymerized in the presence of a known catalyst such as Ziegler-Natta catalyst or metallocene. The 4-methyl-1-pentene polymer employed in the present invention may be either freshly prepared in this manner or purchased ready-made from suppliers. Examples of commercially available 4-methyl-1-pentene polymer products include “TPX®” available from Mitsui Chemicals, Inc.

The 4-methyl-1-pentene polymer is preferably crystalline. More specifically, the 4-methyl-1-pentene is preferably isotactic or syndiotactic, more preferably isotactic. There are no particular limitations to the molecular weight of the 4-methyl-1-pentene polymer so long as moldability and mechanical properties are ensured.

Outermost layer A may contain resin other than the 4-methyl-1-pentene polymer so long as the objective of the present invention is not impaired.

Outermost layer A may also contain additives so long as the objective of the present invention is not impaired. Examples of additives include additives generally blended in polyolefins, including heat stabilizers, weather stabilizers, anticorrosive agents, copper inhibitors, and antistatic agents. The added amount of such additives is preferably 0.0001-10 parts by mass per 100 parts by mass of 4-methyl-1-pentene polymer resin.

Base material layer C is the center layer of the mold release film and serves as a film base. Thus, base material layer C preferably has excellent heat resistance and mechanical properties. In particular, the resin used for base material layer C as a main component preferably has higher strength and creep resistance at high temperatures than 4-methyl-1-pentene polymers, which are contained in outermost layers A as a main component. Herein, “high temperatures” means mold temperatures employed when manufacturing a semiconductor resin package.

Examples of such resins for base material layer C include polycarbonate resins, polyester resins, and polyamide resins. Of these, polyamide resins are preferable, with aliphatic polyamide resins being more preferable. These polyamide resins have high adhesion to modified 4-methyl-1-pentene polymers contained in adhesive layer B (described later) compared to polyester resins such as polyethylene terephthalate resins, thus effectively preventing layer separation between outermost layer A and base material layer C. Aliphatic polyamide resins refer to resins prepared by ring-opening polymerization of lactams; polycondensation reactions of aliphatic diamines with aliphatic dicarboxylic acids; or polycondensation reactions of aliphatic aminocarboxylic acids.

Examples of aliphatic polyamides prepared by ring-opening polymerization of lactams include polyamide 6, polyamide 11, polyamide 12, and polyamide 612. Examples of aliphatic polyamides prepared by polycondensation reactions of aliphatic diamines with aliphatic dicarboxylic acids include polyamide 66, polyamide 610, polyamide 46, polyamide MXD6, polyamide 6T, polyamide 6I, and polyamide 9T.

Of these, polyamide 6 and polyamide 66 are preferable, with polyamide 66 being more preferable. This is because the two polyamides, especially polyamide 66, not only have high melting points and high elasticities and therefore offer excellent heat resistance and mechanical properties, but also offer excellent adhesion to adhesive layer B described later. A mold release film which contains base material layer C containing such a polyamide is unlikely to develop wrinkles as well as pinhole tears. Remarkable leakage of encapsulating material through a pinhole tear results in the deposition of some of the encapsulating material onto the mold cavity walls, causing the soiling of the mold readily.

The melting point of the aliphatic polyamide, as measured by differential scanning calorimetry (DSC), is preferably 190° C. or higher. A mold release film in which an aliphatic polyamide contained in base material layer C has a melting point of less than 190° C. is insufficient in heat resistance and is more prone to wrinkling.

Base material layer C may be a multilayer, e.g., 3-layer base material layer C as indicated by the layer configuration C/C′/C. In this case, it is preferable that at least either of base material layer C or base material layer C′ contain polyamide 66.

Base material layer C may further contain other resin than the above-described polyamide resins. Examples of other resins include heat resistant elastomers which have higher resistance to creep under tensile stress or compressive stress at high temperatures than 4-methyl-1-pentene polymers, a main component of outermost layer A; and heat resistant elastomers which are less prone to stress relaxation and thus offer excellent elasticity recovery.

In order to ensure adhesion to adhesive layer B, examples of such heat resistant elastomers are thermoplastic polyamide elastomers and thermoplastic polyester elastomers. These thermoplastic elastomers preferably have melting points of 190° C. or higher as measured by DSC. Even when thermoplastic elastomers whose melting point is less than 190° C. are to be used, they can be crosslinked either chemically by use of a crosslinker or crosslinker aid or physically by irradiation with UV, electron beams or gamma ray, so as to improve creep resistance at high temperatures and elasticity recovery.

Examples of thermoplastic polyamide elastomers include block copolymers which contain polyamide as a hard segment and polyester or polyether as a soft segment. Examples of polyamides which constitute the hard segment include polyamide 6, polyamide 66, polyamide 610, polyamide 612, and polyamide 11. Examples of polyethers which constitute the soft segment include polyethylene glycol (PEG), polypropylene glycol (PPG), and polytetramethylene glycol (PTMG).

Examples of thermoplastic polyester elastomers include block copolymers which contain as a hard segment a crystalline polymer segment consisting of a crystalline aromatic polyester unit, and as a soft segment an amorphous polymer segment consisting of a polyether unit or aliphatic polyester unit. Examples of crystalline polymers, consisting of a crystalline aromatic polyester unit, of the hard segment include polybutylene terephthalate (PBT) and polybutylene napthalate (PBN). Examples of amorphous polymers, consisting of a polyether unit, of the soft segment include polytetramethylene ether glycol (PTMG). Examples of amorphous polymers, consisting of an aliphatic polyester unit, of the soft segment include aliphatic polyesters such as polycaprolactone (PCL). Specific examples of thermoplastic polyester elastomers include block copolymers of polybutylene terephthalate (PBT) with polytetramethylene ether glycol (PTMG); block copolymers of polybutylene terephthalate (PBT) with polycaprolactone (PCL); and block copolymers of polybutylene napthalate (PBN) with aliphatic polyesters.

Base material layer C may also contain known additives so long as the objective of the present invention is not impaired. In a case where base material layer C contains polyamide resin as a main component, examples of additives to be added are known additives generally blended into polyamide resins, including heat stabilizers containing copper compound for improving heat aging resistance, and lubricants such as calcium stearate and aluminum stearate.

Adhesive layer B is placed between base material layer C and each of outermost layers A, and serves to bond together the base material layer C and outermost layers A. By providing adhesive layers B it is possible to prevent, upon mold clamping or injection molding, the occurrence of layer separation between base material layer C and outermost layer A at a portion of the mold release film where stress concentration is likely to occur. A portion where stress concentration is likely to occur is, for example, the outer edge of the mold cavity (i.e., the boundary between the cavity surface and parting surface of the mold). Adhesive layer B preferably contains a material which is compatible with both of outermost layer A and base material layer C.

Adhesive layer B preferably contains a 4-methyl-1-pentene polymer which has been modified in such a way as to become compatible with a 4-methyl-1-pentene polymer contained in outermost layer A as a main component, more specifically a 4-methyl-1-pentene polymer which has been modified to have polar groups. This is because base material layer C preferably contains polyamide resin, which polyamide resins are compatible with polar groups.

4-Methyl-1-pentene polymers modified to have polar groups can be prepared by any desired process. It is preferable to modify 4-methyl-1-pentene polymers with unsaturated carboxylic acids and/or acid anhydrides thereof (hereinafter collectively referred to as “unsaturated carboxylic acids and the like”).

More specifically, it is preferable to copolymerize 4-methyl-1-pentene polymers with unsaturated carboxylic acids and the like, more preferably to graft-polymerize 4-methyl-1-pentene polymers with unsaturated carboxylic acids and the like. Graft polymerization of 4-methyl-1-pentene polymers with unsaturated carboxylic acids and the like can be accomplished with any desired process. To effect graft polymerization, 4-methyl-1-pentene polymers and unsaturated carboxylic acids and the like may be melt-kneaded in the presence of peroxide or the like, for example.

For the 4-methyl-1′-pentene polymers, those described above can be used. The limiting viscosity [η] of the 4-methyl-1-pentene polymer prior to modification, measured in decahydronapthalene at 135° C., is preferably 0.5-25 dl/g, more preferably 0.5-5 dl/g.

Examples of unsaturated carboxylic acids and the like include C₃₋₂₀ unsaturated compounds having carboxylic group(s) and unsaturated group(s); and C₃₋₂₀ unsaturated compounds having carboxylic anhydride group(s) and unsaturated group(s). Examples of unsaturated group(s) include vinyl group, vinylene group, and unsaturated cyclic hydrocarbons.

Specific examples of unsaturated carboxylic acids and the like include unsaturated monocarboxylic acids such as acrylic acid and methacrylic acid; unsaturated dicarboxylic acids such as maleic acid, fumaric acid, itaconic acid, citraconic acid, allylsuccinic acid, mesaconic acid, glutaconic acid, nadic acid TM, methylnadic acid, tetrahydrophthalic acid, and methylhexahydrophthalic acid; and unsaturated dicarboxylic anhydrides such as maleic anhydride, itaconic anhydride, citraconic anhydride, allylsuccinic anhydride, glutaconic anhydride, nadic TM anhydride, methylnadic anhydride, tetrahydrophthalic anhydride, and methyltetrahydrophthalic anhydride. These compounds may be used alone or in combination. Of these, maleic acid, maleic anhydride, nadic acid TM and nadic TM anhydride are preferable, with maleic anhydride being more preferable.

The graft ratio in the modified 4-methyl-1-pentene polymer is preferably 20 mass % or less, more preferably 0.1-5 mass %, and further preferably 0.5-2 mass %. 4-Methyl-1-pentene polymers whose graft ratio falls within the range offer excellent adhesion to outermost layer A and base material layer C.

Preferably, the modified 4-methyl-1-pentene polymer contains substantially no crosslink structure. The absence of crosslink structure can be confirmed by dissolving the polymer into an organic solvent such as p-xylene and determining the absence gel-like solid in the solution.

The limiting viscosity [η] of the modified 4-methyl-1-pentene polymer as measured in decahydronapthalene at 135° C. is preferably 0.2-10 dl/g, more preferably 0.5-5 dl/g.

Adhesive layer B may contain only a modified 4-methyl-1-pentene polymer as a main component, but preferably contains as a main component a mixture of a modified 4-methyl-1-pentene polymer and other α-olefin polymer(s). In the latter case, the ratio of the modified 4-methyl-1-pentene polymer in the mixture is preferably 20-40 mass %.

The α-olefin polymers are preferably C₂₋₂₀ α-olefin polymers. Examples of C₂₋₂₀ α-olefin polymers include ethylene polymer, propylene polymer, 1-butene polymer, 1-hexene polymer, 1-octene polymer, 1-decene polymer, 1-tetradecene polymer, and 1-octadecene polymer, with 1-butene polymer being preferable.

The 1-butene polymer is either a homopolymer of 1-butene or a copolymer of 1-butene and a C₂₋₂₀ α-olefin other than 1-butene. Examples of C₂₋₂₀ α-olefins other than 1-butene include ethylene, propylene, 1-hexene, 1-octene, 1-decene, 1-tetradecene, and 1-octadecene, with ethylene and propylene being preferable.

The 1-butene polymer preferably contains 60 mass % or more, more preferably 80 mass % or more, of a repeating unit derived from 1-butene, because such 1-butene polymers offer excellent miscibility (or compatibility) with modified 4-methyl-1-pentene polymers.

The melt flow rate (MFR) of the 1-butene polymer as measured in accordance with ASTM D1238 at a load of 2.16 kg and at 190° C. is preferably 0.01-100 g/10 min, more preferably 0.1-50 g/10 min. 1-Butene polymers having MFR falling within the range offer excellent miscibility (or compatibility) with modified 4-methyl-1-pentene polymers and thus may enhance adhesion of adhesive layer B.

Adhesive layer B may also contain the above-described additives in addition to the main component, as do outermost layer A and base material layer C.

As described above, a mold release film according to the present invention includes base material layer C; a pair of outermost layers A which sandwiches base material layer C; and a pair of adhesive layers B each of which is disposed between base material layer C and outermost layer A. Namely, the mold release film preferably has a symmetrical multilayer structure in which layers are laminated symmetrically with respect to the center layer. This is because symmetrical multilayer structures, when heated in a mold, are less susceptible to deformation (e.g., warpage) caused by difference of coefficient of thermal expansion or moisture absorption. Moreover, the mold release film may include additional layer(s) as needed in addition to base material layer C, outermost layers A and adhesive layers B, so long as such a symmetrical multilayer structure is ensured.

Base material layer C may be formed of either a single layer or two or more layers. In the case where base material layer C is a multilayer, multiple base material layers may be directly stacked on top of each other, or an intervening layer (e.g., adhesive layer) may be interposed between adjacent base material layers.

The following shows some specific examples of a multilayer structure of the mold release film, wherein A denotes outermost layer A, B denotes adhesive layer B, C denotes base material layer C, C′ denotes another base material layer C (intermediate layer), and D denotes an adhesive layer which bonds base material layers C and C′ together:

A/B/C/B/A

A/B/C/C′/C/B/A

A/B/C/D/C′/D/C/B/A

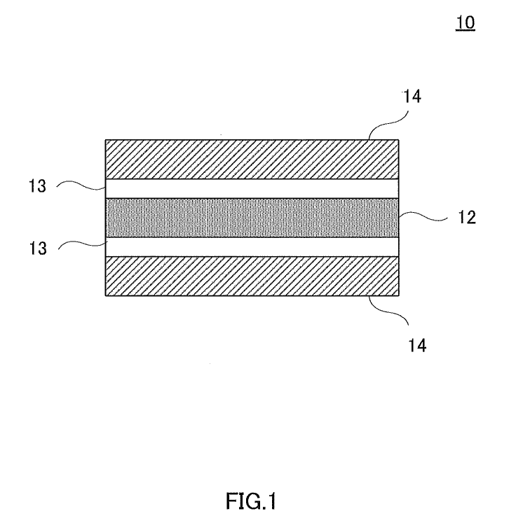

Of these three multilayer structures, “A/B/C/B/A” in which one base material layer C (center layer) is provided is preferable in view of the simplicity of manufacture. FIG. 1 is a schematic view illustrating a preferable example of a structure of a mold release film according to the present invention. As illustrated in FIG. 1, mold release film 10 includes base material layer 12; a pair of outermost layers 14 which sandwiches base material layer 12; and a pair of adhesive layers 13 each of which is disposed between base material layer 12 and outermost layer 14. Base material layer 12 corresponds to above-described base material layer C, outermost layer 14 to above-described outermost layer A, and adhesive layer 13 to above-described adhesive layer B.

Preferably, pairs of layers made of the same material (e.g., the pair of outermost layers A and the pair of adhesive layers B), which are disposed symmetrically with respect to the center layer, are equal in thickness, because by so doing the differences in deformation amount among different layers, caused by the differences in coefficient thermal expansion or other factors, can be cancelled, whereby warpage of the mold release film can be suppressed.

The overall thickness of the mold release film is preferably 15-100 μm. The thickness of each of the layers may be adjusted so that the mold release film as a whole has a thickness falling within this range. More specifically, outermost layer A is preferably 1-30 μm in thickness, adhesive layer B is preferably 1-20 μm in thickness, and base material layer C is preferably 20-40 μm in thickness.

As described above, while the mold release film according to the present invention includes base material layer C with high elastic modulus and high melting point, it also includes adhesive layer B between outermost layer A and base material layer C so as to prevent layer separation between outermost layer A and base material layer C.

However, when the overall thickness of the release film becomes large, particularly when the total thickness of outermost layers A and adhesive layers B becomes large, it become more likely that wrinkles are formed on the side surface of a semiconductor resin package, which may result in appearance deficiencies or poor release performance. Specifically, if the compressive yield stress of the material of the mold release film is smaller than the clamping force generated at the clamping portion around the outer edge of the mold cavity, the semiconductor resin package tend to develop wrinkles on its side surface. In particular, resins used in outermost layer A and adhesive layer B tend to cause wrinkles on the side surface of a semiconductor resin package because they soften when exposed to high temperatures and thus have relatively low compressive yield stresses.

The possible mechanism by which wrinkles are generated on the side surface of a semiconductor resin package will be described. When upper and lower molds are clamped together while placing a mold release film between them, the mold release film between the semiconductor chip board and mold inner surface is crashed by clamping force, allowing a portion of the mold release film to be squeezed out toward the inside of the mold cavity, i.e., toward the vicinity of the semiconductor chip board around the side surface of the semiconductor resin package. As a consequence, a dent is formed in the side surface of the resultant semiconductor resin package, which dent conforms to the surplus mold release film squeezed out. The dent formed in the side surface of the semiconductor resin package takes on a wrinkle-like appearance. Such a dent may also be seen in such semiconductor packages that are manufactured by encapsulating multiple semiconductor chips with encapsulating resin at a time and then singularizing the dies. Appearance deficiencies are particularly likely to seen in such semiconductor packages that are obtained by encapsulating discrete semiconductor chips which have already been singularized (e.g., quad flat non-leaded (QFN) packages) in cases where the side surface of the semiconductor package as manufactured becomes the outer side surface of a final product. Moreover, immediately before film releasing (mold unclamping), the dent observed as a wrinkle in appearance is filled with a surplus mold release film in such a way that it digs into the side walls of the semiconductor resin package. Thus, upon releasing of the semiconductor resin package from the mold, the surplus mold release film remains stuck in the side surface of the semiconductor resin package, which may inhibit mold releasing.

The generation of wrinkles in the side surface of a semiconductor resin package may be avoided by controlling the molding conditions, e.g., by reducing the clamping force, as will be described later. If it is difficult to avoid possible generation of wrinkles only by controlling the molding condition, it is preferable to reduce the overall thickness of the mold release film to an extent that does not causes lengthwise wrinkles, burrs, film breakage, etc., particularly the total thickness of outermost layers A and adhesive layers B to an extent that does not impair releasability and layer adhesion.

The total thickness of outermost layers A and adhesive layers B means a total thickness of the pair of outermost layers A and the pair of adhesive layers B, and is preferably 12-32 μm. Each of outermost layers A is preferably 4-10 μm in thickness, and each of adhesive layers B is preferably 2-6 μm in thickness.

A mold release film according to the present invention preferably has a tensile modulus of 60 MPa or more at a mold temperature, and a tensile strength (as measured when elongated by 500%) of 5 MPa or more at a mold temperature. More specifically, the mold release film preferably has a tensile modulus of 60-300 MPa at 175° C., and a tensile strength (as measured when elongated by 500% of the initial chuck-to-chuck distance) of 5 MPa or more at 175° C. When tensile modulus and tensile strength fall within the respective ranges, wrinkles are difficult to occur at a mold temperature although conformity to the mold shape can be ensured. Tensile modulus and tensile strength may be measured in accordance with the methods given below.

i) Tensile Strength

A 15 mm-width strip of mold release film is cutout from a mold release film of the present invention to prepare a test piece. At this time, the length of the strip should be parallel to the direction in which the mold release film is taken up. The test piece is then attached to a tensile testing machine equipped with a constant-temperature bath whose temperature has been adjusted to the mold temperature, so that the chuck-to-chuck distance becomes 50 mm. The test piece is pulled at a constant rate of 200 mm/min, and a stress measured when the test piece has been elongated by 500% of the initial chuck-to-chuck distance (i.e., chuck-to-chuck distance of 300 mm) without breakage is used as a tensile strength.

i) Tensile Modulus

Tensile modulus is found in accordance with JIS-K 7113 based on the slope of the initial linear portion of a tensile stress-strain curve measured in the above tensile test.

The mold release film according to the present invention may be manufactured by any desired known process, e.g., by co-extrusion of resins of the respective layers or by lamination of films of the respective layers. Additionally, when needed, fine asperities like pearskin finish may be provided on either or both surfaces of the mold release film by use of an embossing roller or the like.

2. Manufacturing Method of Semiconductor Resin Package

A manufacturing method of semiconductor resin package according to the present invention includes a first step of placing a mold release film between a semiconductor chip placed in a mold cavity and a mold inner surface; a second step of encapsulating the semiconductor chip with an encapsulating material; and a third step of separating the semiconductor chip encapsulated from the mold release film.

The semiconductor chip refers to a chip in which semiconductor integrated circuits are formed. When manufacturing a semiconductor resin package, a semiconductor chip is fixed to a lead frame or a substrate called “mother board” or the like. The semiconductor chip to be employed in the present invention is preferably a known semiconductor chip which is fixed to a lead frame or substrate by any known method.

The mold refers to a framework used to make a semiconductor resin package of desired shape by molding. Any known mold shape and any known mold material may be employed.

The encapsulating material refers to a resin composition for encapsulating a semiconductor chip. Any known encapsulating material can be employed; however, it is preferable to employ encapsulating materials which contain as a main component thermosetting resin like epoxy resin.

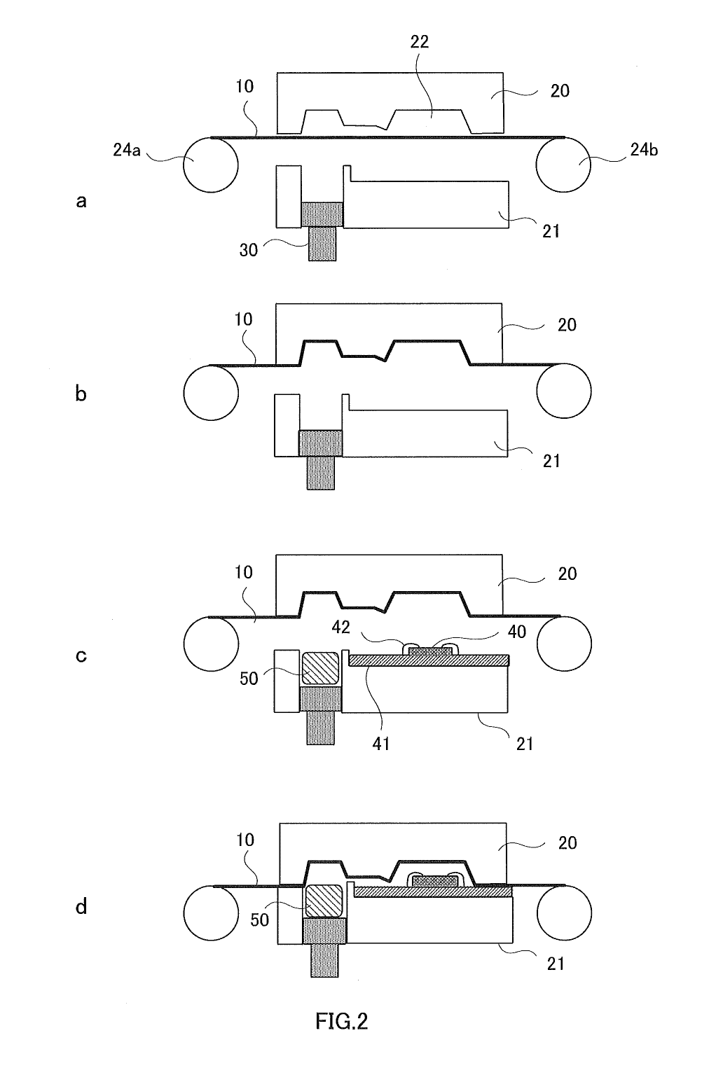

In the first step, the mold release film is placed between the semiconductor chip and the mold. There are no particular limitations to the method of placing the mold release film. FIGS. 2a to 2d illustrate an example of the first step in a manufacturing process of a semiconductor resin package. In the drawing, 10 denotes mold release film; 24a film feed device; 24b film take-up device; 20 upper mold; 21 lower mold; 22 cavity; 30 plunger of a transfer molding machine; 40 semiconductor chip; 41 substrate; 42 wire; and 50 encapsulating material.

As illustrated in FIG. 2a, mold release film 10 is placed between upper mold 20 and lower mold 21 which have been unclamped. At this time, a certain level of tensile force is applied to mold release film 10 by film feed device 24a and film take-up device 24b.

The tensile force applied to mold release film 10 is preferably 0.2-2 MPa in tensile strength. If the tensile force (tensile strength) is less than 0.2 MPa, mold release film 10 tends to become loose and develop wrinkles along its width. On the other hand, if the tensile force (tensile strength) applied to mold release film 10 is greater than 2 MPa, it may result in failure to smoothly secure mold release film 10 to the mold inner surface by vacuum suction and thus to reduce its conformity to the shape of the mold inner surface.

Air trapped in the space between mold release film 10 and upper mold 20 is suctioned out of the mold cavity through exhaust vents (not illustrated) provided in the cavity surface of upper mold 20, thereby causing mold release film 10 to be secured to the parting surface and cavity surface of upper mold 20 by vacuum suction (FIG. 2b). Cavity surface means a surface corresponding to cavity 22 of upper mold 20, and parting surface means a surface where upper mold 20 and lower mold 21 meet when they are clamped together.

Semiconductor chip 40 fixed to board 41 is then placed on lower mold 21 (FIG. 2c), and upper mold 20 and lower mold 21 are clamped together (FIG. 2d). In order to avoid the generation of wrinkles in the side surface of the resultant semiconductor resin package, molding conditions may be controlled, e.g., by lowering the clamping force, to an extent that burrs do not cause any problem.

There are no particular limitations to the mold temperature so long as thermosetting encapsulating materials can be cured. When epoxy resins are employed as a main component of the encapsulating material, mold temperature is preferably set to 160-200° C., more preferably 170-180° C. The depth of mold 20 as measured from the parting surface to the deepest point of cavity 22 is 0.2-2 mm or so, preferably 0.3-1 mm, although it depends on the size of semiconductor chip 40. Mold release film 10 may be pre-heated before positioned in place as illustrated in FIG. 2a. Encapsulating material 50 may also be pre-heated.

Although semiconductor chip 40 fixed to board 41 is placed on lower mold 21 after positioning mold release film 10 in place in FIGS. 2a to 2d, this order may be opposite.

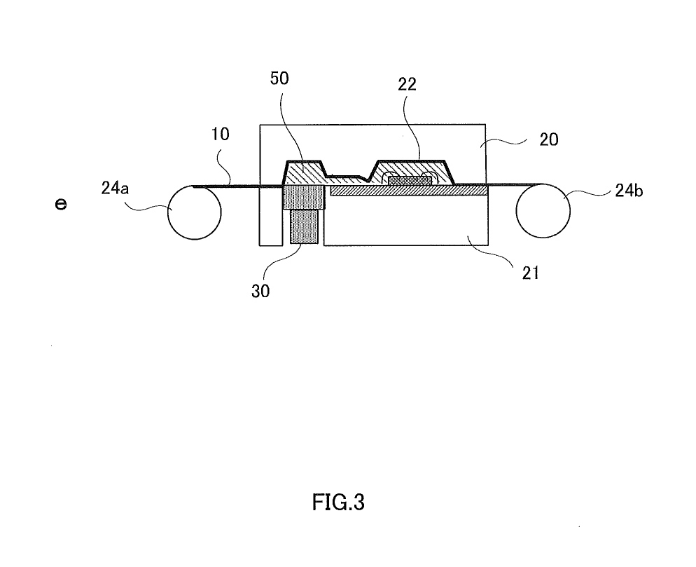

In the second step, semiconductor chip 40 is encapsulated with encapsulating material 50. FIG. 3 illustrates an example of the second step in a manufacturing process of a semiconductor resin package. The references in FIG. 3 are defined the same as in FIGS. 2a to 2d.

As illustrated in FIG. 3, encapsulating material 50, which has been liquefied by being heated to softening point or higher by the heat of the mold, is injected into cavity 22 by the lifting action of plunger 30. With plunger 30 lifted, encapsulating material 50 is retained therein at a given pressure for a given period of time, allowing encapsulating material 50 to cure. At this point, injection rate, retention pressure and retention time are so controlled that resultant semiconductor resin package 61 (later described) is free from any molding failure (i.e., surface profile transfer failure, warpage, sink marks, voids, and burrs). Retention pressure is preferably 1-12 MPa, for example.

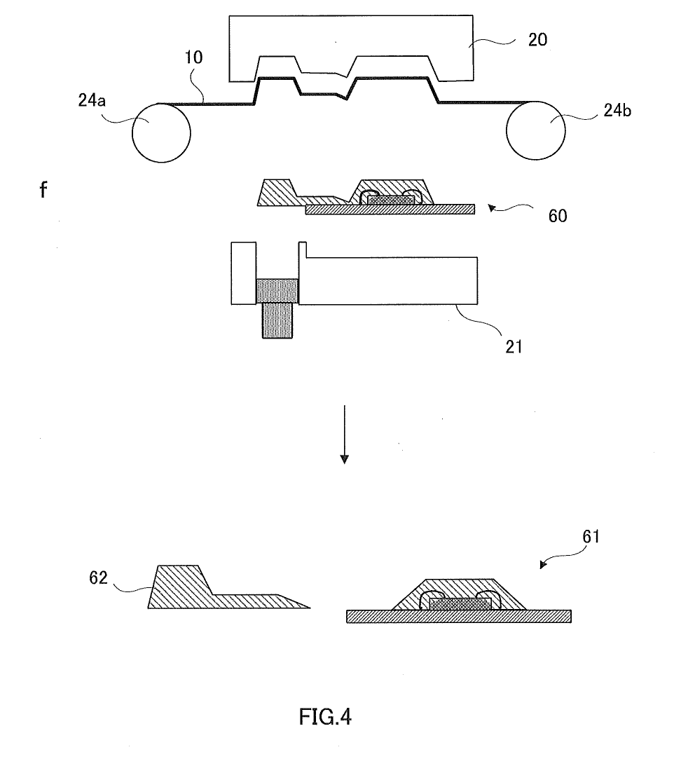

In the third step, the encapsulated semiconductor chip is separated from the mold release film. FIG. 4 illustrates an example of the third step in a manufacturing process of a semiconductor resin package. In FIG. 4, 60 denotes encapsulated semiconductor chip; 61 semiconductor resin package; and 62 runner. The other references in FIG. 4 are defined the same as in FIGS. 2a to 2d.

Upper mold 20 and lower mold 21 are then unclamped, separating encapsulated semiconductor chip 60 from mold release film 10. For its excellent releasability, mold release film 10 can be readily separated from encapsulated semiconductor chip 60, as well as from upper mold 20. Runner 62 is then cutout from encapsulated semiconductor chip 60 to provide semiconductor resin package 61.

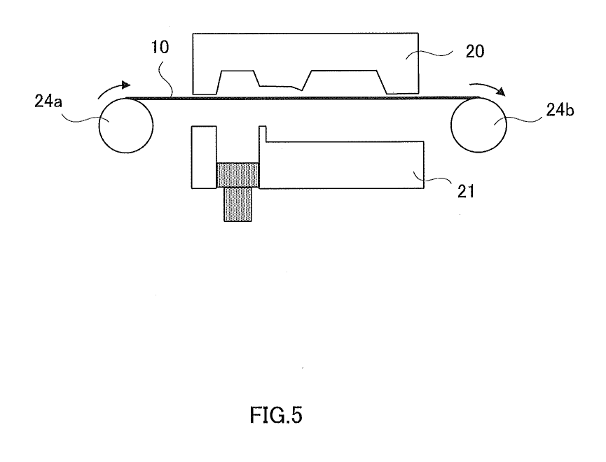

In order to conduct another encapsulating step immediately after the third step, a new mold release film may be reloaded in the mold. Reloading a new mold release film means, after recovering encapsulated semiconductor chip 60, replacing used mold release film 10 with new mold release film 10 at a position between upper mold 20 and lower mold 21 as illustrated in FIG. 2a. FIG. 5 illustrates an example of a process of reloading a new mold release film in the mold after the third step. The references in FIG. 5 are defined the same as in FIGS. 2a to 2d.

As illustrated in FIG. 5, for example, new mold release film 10 is fed by film feed device 24a and placed between upper mold 20 and lower mold 21 while taking up used mold release film 10 by film take-up device 24b. In this way new mold release film 10 is reloaded.

An embodiment has been described in which a semiconductor resin package is manufactured by transfer molding; however, it is also possible to employ other molding techniques such as compression molding and injection molding. For example, when compression molding is employed for manufacturing a semiconductor resin package, a mold release film according to the present invention can be used with reference to the compression molding technique described in “Tokushu Densibuhin Package no Seikeigijutsu”, Mold Processing, Vol. 20, No. 5, pp. 276-287 (2008).

As mold release film 10 according to the present invention has a symmetrical multilayer structure as described above, it is less prone to deformation (e.g., warpage) and wrinkling when placed in the mold. Moreover, when base material layer C (center layer) of mold release film 10 contains an aliphatic polyamide—a polymer that offers excellent mechanical strength at high temperatures—as a main component, lengthwise wrinkles are less likely to form at a mold temperature.

It is also possible to suppress the generation of wrinkles in the side surface of a semiconductor resin package (side wrinkles) by setting the ratio of the total thickness of outermost layers A and adhesive layers B to the overall thickness of the mold release film below a certain value.

Furthermore, mold release film 10 according to the present invention offers excellent mold shape conformity as well as excellent releasability and therefore may allow the resin to smoothly flow across the mold cavity even when the encapsulating process is continuously performed. Mold release film 10 according to the present invention can also retain high releasability from encapsulated semiconductor chip 40. It is thus possible to provide a semiconductor resin package having good dimensional accuracy and less appearance deficiencies like burrs and dents.

### EXAMPLES

(1) Preparation of Material of Outermost Layer A

A copolymer of 4-methyl-1-pentene and 1-decene was prepared by the conventional process. The 1-decene content was set to 2.5 mass %. Hereinafter, the copolymer thus obtained will also be referred to as “A-1”.

(2) Preparation of Material of Adhesive Layer B

Production of modified 4-methyl-1-pentene copolymer

A copolymer of 4-methyl-1-pentene and Diarene 168, a mixture of a C₁₆ α-olefin and C₁₈ α-olefin, available from Mitsubishi Chemical Corporation, was prepared by the conventional process. The Diarene 168 content was set to 6.5 mass %.

98.8 parts by mass of the copolymer above, 1 part by mass of maleic anhydride, and 0.2 parts by mass of 2,5-dimethyl-2,5-di(tert-butylperoxy)hexane as an organic peroxide were mixed together in HENSCHEL MIXER. The mixture was kneaded with a biaxial extruder at 280° C. to produce a modified 4-methyl-1-pentene copolymer graft-modified with maleic anhydride. The graft ratio of the modified 4-methyl-1-pentene copolymer was 0.9 mass %.

Preparation of Material of Adhesive Layer B

25 parts by mass of the modified 4-methyl-1-pentene copolymer prepared above, 50 parts by mass of the copolymer of 4-methyl-1-pentene and Diarene 168 (Diacene 168 content=6.5 mass %), 25 parts by mass of 1-butene copolymer, 0.10 parts by mass of Irganox 1010 (Ciba) as a stabilizer, and 0.03 parts by mass of calcium stearate (Sankyo Organic Chemicals Co., Ltd.) were mixed together in HENSCHEL MIXER at a low rotation speed for 3 minutes. The mixture was extruded with a biaxial extruder at 280° C. to produce adhesive layer B resin (hereinafter also referred to as “B-1”).

(3) Preparation of Material of Base Material Layer C

As a first aliphatic polyamide resin (hereinafter also referred to as “C-1”), polyamide 6 (“Amilan® CM1041LO”, Toray Industries, Inc.; melting point=225° C.) was prepared. As a second aliphatic polyamide resin (hereinafter also referred to as “C-2”), polyamide 66 (“Leona 1700S” Asahi Kasei Chemicals Corporation; melting point=265° C.) was prepared. As a third aliphatic polyamide resin (hereinafter also referred to as “C-3”), polyamide 66 (“Zytel® 42A”, DuPont; melting point=262° C.) was prepared.

### Example 1

The above-described raw layer materials were co-extruded with a T-die molding machine to manufacture a non-stretched mold release film of 400 mm width. The mold release film had a 5-layer structure consisting of three different layers: A-1/B-1/C-1/B-1/A-1, wherein their thicknesses were 15 μm/5 μm/25 μm/5 μm/15 μm, respectively (total thickness=65 μm).

As illustrated in FIGS. 2a to 2d, obtained mold release film 10 was placed between upper mold 20 and lower mold 21. The depth of cavity 22 defined by upper mold 20 and lower mold 21, as measured from the mold parting surface, was 0.8 mm at the deepest point. The tensile applied to mold release film 10 by film feeding device 24a and film take-up device 24b was adjusted to a tensile strength of 1 MPa.

Mold release film 10 was then secured to the parting surface of upper mold 20 by vacuum suction as illustrated in FIG. 2b. Semiconductor chip 40 fixed to board 41 was placed onto lower mold 21 (see FIG. 2c), and then upper mold 20 and lower mold 21 were clamped together (FIG. 2d). The mold temperature at this point was set to 175° C. As encapsulating material 50, a commercially available epoxy resin molding material for encapsulating semiconductor device was employed.

As illustrated in FIG. 3, encapsulating material 50, liquefied by being heated to a temperature higher than softening point by the heat of the mold, was injected into the mold cavity through plunger 30. Encapsulating material 50 was then retained therein at a pressure of 12 MPa for 120 seconds for curing. Mold release film 10 was separated from encapsulated semiconductor chip 60 to manufacture semiconductor resin package 61.

Semiconductor resin package 61 and mold release film 10 after encapsulation were evaluated as described below.

i) Releasability

The mold release film was evaluated for its releasability from the semiconductor resin package based on the following criteria:

A: Mold release film spontaneously peels off upon mold unclamping

B: A portion of mold release film remains on semiconductor resin package 61 or mold

C: Entire mold release film firmly remains on the encapsulated semiconductor chip or mold.

ii) Layer separation

The instance of layer separation of the mold release film at a portion corresponding to the semiconductor resin package upon film releasing was evaluated based on the following criteria:

A: No separation occurred between outermost layer A and base material layer C

B: Slight separation occurred between outermost layer A and base material layer C

C: Remarkable separation occurred between outermost layer A and base material layer C

iii) Top Wrinkles (Lengthwise Wrinkles)

Transfer of a wrinkle to the top surface of the semiconductor resin package was evaluated based on the following criteria:

A: No wrinkle appeared

B: Wrinkle appeared

iv) Side Wrinkles

The depth of the wrinkle formed on the side surface of the semiconductor resin package (except at the air vent and gate) was evaluated in the following manner:

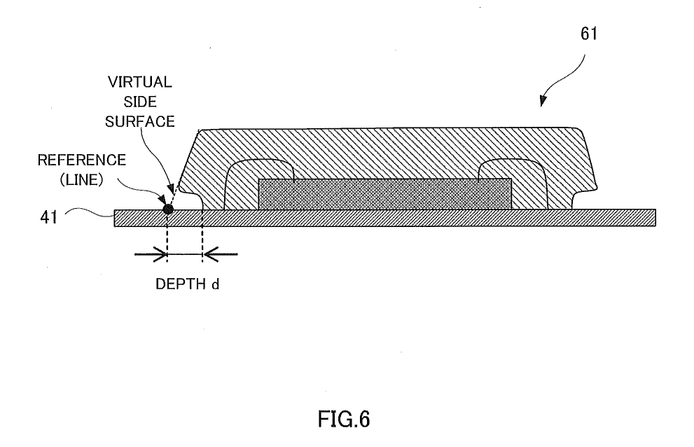

FIG. 6 is a cross-sectional view for explaining an exemplary method of measuring the depth of a side wrinkle formed on the side surface of the semiconductor package 61. Specifically, using a dicer, semiconductor resin package 61 was vertically cut with respect to the top surface to expose a section as illustrated in FIG. 6. Using a scale-reading microscope, a point (line) at which an otherwise flat side surface of the package (virtual side surface without any wrinkle) intersects with the surface board 41 was defined as a reference point (line), and then the distance from the reference point to the bottom of the recessed portion in the side surface (depth d) was measured. The degree of the side wrinkle depth thus measured was ranked as follows:

S: less than 100 μm

A: 100 μm to less than 200 μm

B: 200 μm to less than 300 μm

C: 300 μm or greater

The deeper the side wrinkle, the more it is likely to cause outstanding appearance deficiencies in semiconductor resin package 61, as well as poor releasability of release film 10 from semiconductor resin package 61. For these reasons, the side wrinkle depth is preferably minimized.

v) Warpage

The degree of warpage of the mold release film was evaluated based on the following criteria:

A: No warpage occurred

B: Slight warpage occurred; no practical problem

C: Large warpage occurred; the film is unusable

vi) Pinhole Tearing

The generation of a pinhole tear in the used mold release film 10 and attachment of the encapsulating resin on the mold cavity surface were evaluated by visual observation based on the following criteria:

A: No pinhole tear occurred

B: Tiny pinhole tear occurred, but attachment of leaked encapsulating resin to the mold was not observed

### Example 2

Mold release film 10 was manufactured as in Example 1 except that the combination of layer thicknesses was set to 10 μm/5 μm/15 μm/5 μm/10 μm (total thickness=45 μm). Semiconductor resin package 61 was then manufactured using mold release film 10 and evaluated as in Example 1.

### Example 3

Mold release film 10 was manufactured as in Example 1 except that the combination of layer thicknesses was set to 10 μm/5 μm/20 μm/5 μm/10 μm (total thickness=50 μm). Semiconductor resin package 61 was then manufactured using mold release film 10 and evaluated as in Example 1.

### Example 4

Mold release film 10 was manufactured as in Example 11 except that the combination of layer thicknesses was set to 10 μm/3 μm/24 μm/3 μm/10 μm (total thickness=50 μm). Semiconductor resin package 61 was then manufactured using mold release film 10 and evaluated as in Example 1.

### Example 5

Mold release film 10 was manufactured as in Example 1 except that the material of base material layer C was changed to C-2. Semiconductor resin package 61 was then manufactured using mold release film 10 and evaluated as in Example 1.

### Example 6

Mold release film 10 was manufactured as in Example 2 except that the material of base material layer C was changed to C-2. Semiconductor resin package 61 was then manufactured using mold release film 10 and evaluated as in Example 1.

### Example 7

Mold release film 10 was manufactured as in Example 3 except that the material of base material layer C was changed to C-2. Semiconductor resin package 61 was then manufactured using mold release film 10 and evaluated as in Example 1.

### Example 8

Mold release film 10 was manufactured as in Example 4 except that the material of base material layer C was changed to C-2. Semiconductor resin package 61 was then manufactured using mold release film 10 and evaluated as in Example 1.

### Example 9

Mold release film 10 was manufactured as in Example 1 except that the material of base material layer C was changed to C-2 and that the combination of layer thicknesses was set to 6 μm/3 μm/32 μm/3 μm/6 μm (total thickness=50 μm). Semiconductor resin package 61 was then manufactured using mold release film 10 and evaluated as in Example 1.

### Example 10

Mold release film 10 was manufactured as in Example 3 except that the material of base material layer C was changed to C-3. Semiconductor resin package 61 was then manufactured using mold release film 10 and evaluated as in Example 1.

### Example 11

Mold release film 10 was manufactured as in Example 4 except that the material of base material layer C was changed to C-3. Semiconductor resin package 61 was then manufactured using mold release film 10 and evaluated as in Example 1.

### Example 12

Mold release film 10 was manufactured as in Example 9 except that the material of base material layer C was changed to C-3. Semiconductor resin package 61 was then manufactured using mold release film 10 and evaluated as in Example 1.

### Comparative Example 1

A 400 mm-width non-stretched release film was manufactured as in Example 1 except that a 3-layer structure consisting of two different layers (A-1/C-1/A-1), with their thicknesses set to 25 μm/15 μm/25 μm, respectively (total thickness=65 μm), was employed. A semiconductor resin package was then manufactured using the mold release film thus manufactured and evaluated as in Example 1.

### Comparative Example 2

A 400 mm-width non-stretched release film was manufactured as in Comparative Example 1 except that the combination of the layer thicknesses was set to 15 μm/15 μm/15 μn (total thickness=45 μm). A semiconductor resin package was then manufactured using the mold release film thus manufactured and evaluated as in Example 1.

### Comparative Example 3

A 400 mm-width non-stretched release film was manufactured as in Comparative Example 1 except that a 3-layer structure consisting of three different layers (A-1/B-1/C-2), which is asymmetrical with respect to the center layer, with their thicknesses set to 20 μm/5 μm/25 μm, respectively (total thickness=50 μm), was employed. A semiconductor resin package was then manufactured using the mold release film thus manufactured and evaluated as in Example 1.

The evaluation results are summarized in Table 1.

TABLE 1

| | | Mold release film | | | | | | | | |
|---|---|---|---|---|---|---|---|---|---|---|
| | | | | Total | Evaluations | | | | | |
| | | | Layer thickness | thickness | | Layer | Wrinkle | | | |
| | Feature | Layer configuration | [μm] | [μm] | Releasability | separation | Top | side | Warpage | Tear |
| Ex. 1 | C-1 layer: PA6 | A-1/B-1/C-1/B-1/A-1 | 15/5/25/5/15 | 65 | A | A | A | B | A | A |
| Ex. 2 | (Amilan ® 1041LO) | | 10/5/15/5/10 | 45 | | | | A | | B |
| Ex. 3 | | | 10/5/20/5/10 | 50 | | | | B | | |
| Ex. 4 | | | 10/3/24/3/10 | 50 | | | | A | | A |
| Ex. 5 | C-2 layer: PA66 | A-1/B-1/C-2/B-1/A-1 | 15/5/25/5/15 | 65 | | | | B | | A |
| Ex. 6 | (Leona ® 1700S) | | 10/5/15/5/10 | 45 | | | | S | | B |
| Ex. 7 | | | 10/5/20/5/10 | 50 | | | | A | | A |
| Ex. 8 | | | 10/3/24/3/10 | 50 | | | | S | | |
| Ex. 9 | | | 6/3/32/3/6 | 50 | | | | | | |
| Ex. 10 | C-3 layer: PA66 | A-1/B-1/C-3/B-1/A-1 | 10/5/20/5/10 | 50 | | | | A | | |
| Ex. 11 | (Zytel ® 42A) | | 10/3/24/3/10 | 50 | | | | S | | |
| Ex. 12 | | | 6/3/32/3/6 | 50 | | | | | | |
| Comp. Ex. 1 | Layer B: not provided | A-1/C-1/A-1 | 25/15/25 | 65 | B | C | A | C | A | B |
| Comp. Ex. 2 | Layer B: not provided | A-1/C-1/A-1 | 15/15/15 | 45 | B | C | | A | A | B |
| Comp. Ex. 3 | Asymmetrical | A-1/B-1/C-1 | 20/5/25 | 50 | C | A | | S | C | A |

As seen from Table 1, the mold release films prepared in Examples 1-12 not only offered excellent releasability, but also were able to suppress the occurrence of all of layer separation, wrinkling, warpage, and tearing. It can also be seen from Table 1 that the mold release films prepared in Examples 5-12 where base material layer C contains polyamide 66 (PA66), particularly the mold release films prepared in Examples 6-12 where the outermost layers A and adhesive layers B are small in thickness, can significantly reduce the depth of a side wrinkle in the semiconductor resin package. This is considered to be due to high heat resistance of base material layer C as well as to the thinness of outermost layers A and adhesive layers B, which have relatively low compressive yield stresses. It should be noted, however, that too thin base material layer C may result in the generation of a tiny tear in the mold release film. This may be due to the fact that thin mold release films cannot retain sufficient mechanical strength.

By contrast, it can be seen from Table 1 that the release films prepared in Comparative Examples 1-3 cannot suppress the occurrence of all of layer separation, wrinkling, warpage, and tearing. It can be seen from Table 1 that the mold release films prepared in Comparative Examples 1-2, where no adhesive layer B is provided, were inferior in terms of releaseability, layer separation and tearing, particularly in terms of layer separation. Moreover, it can be seen from Table 1 that the mold release film prepared in Comparative Example 3 which has an asymmetrical multilayer structure not only showed warpage, but also offered poor releasability.

The present application claims the priority of Japanese Patent Application No.2008-219815, filed on Aug. 28, 2008, including the specification, drawings and abstract, is incorporated herein by reference in its entirety.

### INDUSTRIAL APPLICABILITY

The mold release film according to the present invention offers excellent releasability from a semiconductor resin package as well as are less prone to warpage and wrinkling. By manufacturing a semiconductor resin package using the mold release film, it is possible to provide a semiconductor resin package with good dimensional accuracy. Therefore, the present invention is useful for manufacturing a semiconductor resin package.

### REFERENCE SIGNS LIST

10: mold release film
12: base material layer C
13: adhesive layer B
14: outermost layer A
20: upper mold
21: lower mold
22: cavity
24a: film feed device
24b: film take-up device
30: plunger
40: semiconductor chip
41: board
42: wire
50: encapsulating material
60: encapsulated semiconductor chip
61: semiconductor package
62: runner

1. A mold release film for manufacturing a semiconductor resin package comprising:
at least one base material layer C;
a pair of outermost layers A which sandwiches base material layer C and contains a 4-methyl-1-pentene polymer as a main component; and
a pair of adhesive layers B which bonds outermost layers A to base material layer C.

2. The mold release film according to claim 1, wherein base material layer C contains a polyamide resin, and adhesive layers B contain a modified 4-methyl-1-pentene polymer obtained by modifying a 4-methyl-1-pentene polymer with a unsaturated carboxylic acid and/or acid anhydride thereof.

3. The mold release film according to claim 2, wherein adhesive layers B contains a modified 4-methyl-1-pentene polymer obtained by graft-modifying a 4-methyl-1-pentene polymer with maleic anhydride.

4. The mold release film according to claim 2, wherein the polyamide resin is polyamide 6 or polyamide 66.

5. The mold release film according to claim 1, wherein the mold release film contains one base material layer C.

6. The mold release film according to claim 1, wherein the total thickness of the pair of outermost layers A and the pair of adhesive layers B is 32 μm or less.

7. The mold release film according to claim 1, wherein the mold release film has a symmetrical multilayer structure in which base material layer C is the center layer.

8. A method of manufacturing a semiconductor resin package comprising:
placing a semiconductor chip into a cavity of a mold;
placing the mold release film according to claim 1 between the semiconductor chip and an inner surface of the mold;
injecting an encapsulating material into the cavity of the mold to encapsulate the semiconductor chip therein; and
separating the semiconductor chip encapsulated with the encapsulating material from the mold release film.

9. The mold release film according to claim 1, wherein the mold release film is used in a manufacturing process of a semiconductor resin package which comprises the steps of:
placing a semiconductor chip in a cavity of a mold;
placing the mold release film between the semiconductor chip and an inner surface of the mold;
injecting an encapsulating material into the cavity of the mold to encapsulate the semiconductor chip therein; and
separating the semiconductor chip encapsulated with the encapsulating material from the mold release film.
